(19) United States
(12) Patent Application Publication
(10) Pub. No.: US 2022/0121109 A1
(43) Pub. Date: Apr. 21, 2022

(54) SUBSTRATE FOR MASK BLANK, SUBSTRATE WITH CONDUCTIVE FILM, SUBSTRATE WITH MULTILAYER REFLECTIVE FILM, REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventor: Hideaki NARAHARA, Tokyo (JP)

(73) Assignee: HOYA CORPORATION, Tokyo (JP)

(21) Appl. No.: 17/431,702

(22) PCT Filed: Mar. 24, 2020
(86) PCT No.: PCT/JP2020/013139

§ 371 Date: Aug. 17, 2021

(30) Foreign Application Priority Data
Mar. 28, 2019 (JP) 2019-063692

(51) Int. Cl. G03F 1/60; G03F 1/24

(52) U.S. Cl. CPC G03F 1/60; G03F 1/24

(57) ABSTRACT

Provided is a mask blank substrate whose surface shape as of the time after the substrate is set on a mask stage of an exposure apparatus can be accurately calculated.

A mask blank substrate 10 includes a first main surface 12a on which a transfer pattern is formed and a second main surface 12b that is opposed to the first main surface 12a and is to be electrostatically chucked to a mask stage of an exposure apparatus. The first main surface 12a includes a first area 20a located around the center and a second area 20b located outside the first area 20a. The second main surface 12b includes a third area 20c located around the center and a fourth area 20d located outside the third area 20c. The angle α formed between the least squares plane of the first area 20a and the least squares plane of the third area 20c is less than 1.2°. The PV value of a surface of each of the second area 20b and the fourth area 20d is 400 nm or less.

### TECHNICAL FIELD

The present disclosure relates to a mask blank substrate, a substrate with a conductive film, a substrate with a multilayer reflective film, a reflective mask blank, a reflective mask, and a method of manufacturing a semiconductor device.

### BACKGROUND ART

In general, a process of manufacturing a semiconductor device includes forming a fine pattern by using photolithography. To form a fine pattern, a number of transfer masks called photomasks are usually used. In general, the transfer mask is obtained by providing a fine pattern made of a metal thin film or the like on a light-transmissive glass substrate, and photolithography is also used for manufacturing the transfer mask.

For manufacturing a transfer mask using photolithography, a mask blank with a thin film (for example, a light shielding film) is used, the thin film being intended to form a transfer pattern (mask pattern) on a light-transmissive substrate such as a glass substrate. A method of manufacturing a transfer mask using such a mask blank includes drawing a desired pattern on a resist film formed on the mask blank; after the drawing, developing the resist film to form a desired resist pattern; etching the thin film using the resist pattern as a mask; and peeling off and removing the remaining resist pattern. In the developing, a developer is supplied to the resist film formed on the mask blank after a desired pattern is drawn on the resist film. As a result, a portion of the resist film soluble in the developer is dissolved, thereby forming a resist pattern. In the etching, by using the resist pattern as a mask, a portion of the thin film not covered with the resist pattern and thus exposed is removed by dry etching or wet etching. As a result, a desired mask pattern is formed on the light-transmissive substrate.

Known types of transfer masks include a phase shift-type mask in addition to a conventional binary-type mask that has a light-shielding film pattern made of a chromium-based material on a light-transmissive substrate. The phase shift-type mask includes a light-transmissive substrate and a phase shift film formed on the light-transmissive substrate. The phase shift film, which has a predetermined phase difference, is formed of, for example, a material containing a molybdenum silicide compound. In addition, a binary-type mask that employs a material containing a silicide compound of a metal such as molybdenum as a light shielding film has been increasingly used. These binary-type and phase shift-type masks are herein collectively referred to as a transmissive mask. In addition, a binary-type mask blank and a phase shift-type mask blank, which are original plates used for transmissive masks, are collectively referred to as a transmissive mask blank.

In recent years, along with higher integration of semiconductor devices, a fine pattern exceeding the transfer limit of a conventional photolithography method employing ultraviolet light has been in demand in the semiconductor industry. As a technology for achieving formation of such a fine pattern, EUV lithography, which is an exposure technology employing extreme ultraviolet (hereinafter referred to as “EUV”) is regarded as promising. Here, EUV light refers to light in a wavelength band of a soft X-ray region or a vacuum ultraviolet region, and more specifically, to light having a wavelength of about 0.2 to 100 nm. As a transfer mask used in the EUV lithography, a reflective mask has been proposed. In such a reflective mask, a multilayer reflective film that reflects exposure light is formed on a substrate, and an absorber film that absorbs the exposure light is formed on the multilayer reflective film. A transfer pattern is formed on the absorber film of the reflective mask.

Patent Literature 1 discloses a reflective mask blank including, on a substrate, a multilayer reflective film that reflects exposure light and an absorber layer that is formed on the multilayer reflective film and absorbs the exposure light, in which a surface of the reflective mask blank opposite to the surface on which a transfer pattern is formed has a convex shape. It is disclosed that the reflective mask blank makes it possible to solve a problem of attraction failure in fixing the reflective mask to a mask stage of an exposure apparatus using an electrostatic chuck.

### CITATION LIST

### Patent Literature

Patent Literature 1: JP 2008-103481 A

### SUMMARY OF DISCLOSURE

### Technical Problem

When a transfer pattern is transferred to a transfer-receiving object such as a semiconductor substrate by using a reflective mask, the reflective mask is set on a mask stage of an exposure apparatus with the surface of the reflective mask on which the transfer pattern is formed facing downward. On a surface (back surface) of the reflective mask opposite to the side on which the transfer pattern is formed, a conductive film is formed for attracting the reflective mask to the mask stage of the exposure apparatus by an electrostatic chuck.

Therefore, when the reflective mask is set on the mask stage of the exposure apparatus, substantially all the back surface of the reflective mask is attracted to the mask stage of the exposure apparatus by the electrostatic chuck. While the mask stage of the exposure apparatus is flat, the back surface of the reflective mask is not completely flat but has irregularities. Therefore, the shape of irregularities on the back surface of the reflective mask is transferred to the surface (front surface) of the reflective mask on which the transfer pattern is formed.

For example, if there is a convex shape on the back surface of the reflective mask, the convex shape is pressed downward by the mask stage, with the result that the front surface of the reflective mask opposed to the position of the convex shape is deformed downward by the height of the convex shape.

To the contrary, if, for example, there is a concave shape on the back surface of the reflective mask, the reflective mask is pulled upward by the concave shape toward the mask stage, with the result that the front surface of the reflective mask opposed to the position of the concave shape is deformed upward by the depth of the concave shape.

As described above, a conventional reflective mask is problematic in that it is difficult to accurately transfer a transfer pattern to a transfer-receiving object such as a semiconductor substrate because, before and after the reflective mask is set on a mask stage of an exposure apparatus, the shape of the main surface on which the transfer pattern is formed is changed.

A conceivable solution to such a problem may be measuring the shapes of the front and back surfaces of a mask blank substrate (or a reflective mask blank or a reflective mask) in advance by using a surface shape measuring apparatus, and, through simulation based on data obtained by the measurement, calculating the front surface shape of the mask blank substrate (or the reflective mask blank or the reflective mask) that has been set on a mask stage of an exposure apparatus. If the front surface shape of the mask blank substrate (or the reflective mask blank or the reflective mask) that has been set on the mask stage is known in advance through simulation, the shape of the transfer pattern on the reflective mask that has been set on the mask stage of the exposure apparatus can be controlled to be a desired shape by correcting the shape of the transfer pattern drawn by a drawing apparatus.

However, the front surface and the back surface of the mask blank substrate are not completely parallel. For this reason, regarding a conventional mask blank substrate, it is difficult to accurately associate the front surface shape data measured by a surface shape measuring apparatus with the back surface shape data.

Specifically, to measure the surface shape of a mask blank substrate (or a reflective mask blank or a reflective mask) with a surface shape measuring apparatus, the surface is divided into a plurality of areas in a grid (for example, 197 μm×197 μm areas) and the surface shape is measured for each of the divided areas. However, since the front surface and the back surface of a mask blank substrate are not completely parallel, it is conventionally difficult to accurately associate the shape data measured in a certain area of the front surface with the shape data measured at a position opposed to that area. Therefore, it is conventionally difficult to accurately calculate, through simulation, the surface shape of a mask blank substrate (or a reflective mask blank or a reflective mask) that has been set on a mask stage.

The present disclosure has been made in view of the above circumstances, and an aspect of the present disclosure is to provide a mask blank substrate, a substrate with a conductive film, a substrate with a multilayer reflective film, a reflective mask blank, a reflective mask, and a method of manufacturing a semiconductor device, in which the surface shape of the substrate that has been set on a mask stage of an exposure apparatus can be accurately calculated.

### Solution to Problem

In order to solve the above problems, the present disclosure has the following configurations.

(1) A mask blank substrate having a substantially quadrangular planar shape and a size of 152 mm×152 mm, the mask blank substrate including:

a first main surface on which a transfer pattern is formed and a second main surface that is opposed to the first main surface and is to be fixed to a mask stage of an exposure apparatus, in which

the first main surface includes a first area located around a center and a second area located outside the first area,

the second main surface includes a third area located around a center and a fourth area located outside the third area,

an angle α formed between a least squares plane of the first area and a least squares plane of the third area is less than 1.2°, and

a PV value of a surface of each of the second area and the fourth area is 400 nm or less.

(2) The mask blank substrate according to (1), in which the first area is an area on which the transfer pattern is formed and has a size of 132 mm×132 mm or more with reference to the center of the substrate.

(3) The mask blank substrate according to (1) or (2), in which the third area has a size of 142 mm×142 mm or more with reference to the center of the substrate.

(4) The mask blank substrate according to any one of (1) to (3), in which each of the second area and the fourth area is an area outside a 148 mm×148 mm area with reference to the center of the substrate.

(5) The mask blank substrate according to any one of (1) to (4), in which the mask blank substrate is a reflective mask blank substrate.

(6) A substrate with a conductive film, the substrate including the conductive film on the second main surface of the mask blank substrate according to any one of (1) to (5).

(7) A substrate with a multilayer reflective film, the substrate including the multilayer reflective film in which a high refractive index layer and a low refractive index layer are alternately layered, in which the multilayer reflective film is on the first main surface of the mask blank substrate according to any one of (1) to (6).

(8) A reflective mask blank including an absorber film serving as a transfer pattern, in which the absorber film is on the multilayer reflective film of the substrate with a multilayer reflective film according to (7).

(9) A reflective mask including an absorber pattern, in which the absorber pattern is on the multilayer reflective film in the reflective mask blank according to (8), and is provided by patterning the absorber film.

(10) A method of manufacturing a semiconductor device, the method including performing a lithography process that employs an exposure apparatus using the reflective mask according to (9) to form a transfer pattern on a transfer-receiving object.

### BRIEF DESCRIPTION OF DRAWINGS

FIG. 1 is a perspective view of a mask blank substrate.

FIG. 2 is a partial cross-sectional view of the mask blank substrate.

FIG. 3 is a plan view of a first main surface.

FIG. 4 is a plan view of a second main surface.

FIG. 5 is a schematic diagram for calculating a maximum distance by which a point on a plane is shifted when the plane is rotated.

FIG. 6 is a schematic diagram illustrating a substrate with a multilayer reflective film.

FIG. 7 is a schematic diagram illustrating a reflective mask blank.

FIG. 8 is a schematic diagram illustrating a reflective mask.

### DESCRIPTION OF EMBODIMENTS

Embodiments of the present disclosure will be described in detail below.

[Mask Blank Substrate]

First, a mask blank substrate of the present embodiment will be described.

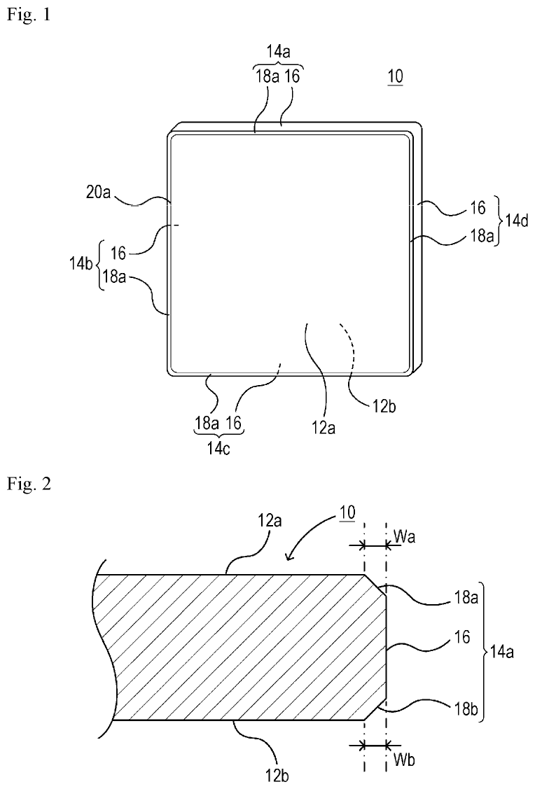

FIG. 1 is a perspective view illustrating a mask blank substrate 10 according to the present embodiment. FIG. 2 is a partial cross-sectional view of the mask blank substrate 10 of the present embodiment.

The mask blank substrate 10 (which may be hereinafter simply referred to as a substrate 10) is formed of a substantially quadrangular (preferably square) plate-like body having a size of 152 mm×152 mm. The mask blank substrate 10 has two main surfaces 12a and 12b and four end surfaces 14a to 14d. The surface on which a thin film is formed to serve as a transfer pattern is herein called a first main surface 12a. The surface that is opposed to the first main surface 12a and is to be electrostatically chucked to a mask stage of an exposure apparatus is called a second main surface 12b.

Note that “upper” as used herein does not necessarily mean an upper side with respect to the vertical direction. In addition, “lower” does not necessarily mean a lower side with respect to the vertical direction. These terms are used merely for convenience to explain the positional relationship between members or parts.

The four end surfaces 14a to 14d are adjacent to the four sides, respectively, of each of the first main surface 12a and the second main surface 12b that are substantially quadrangular.

Each of the four end surfaces 14a to 14d has a side face 16 and two chamfered faces 18a and 18b (see FIG. 2) formed between the side face 16 and the main surfaces 12a and 12b.

The side face 16 is a face substantially perpendicular to the two main surfaces 12a and 12b, and may be called a “T face”.

The chamfered faces 18a and 18b are faces formed between the two main surfaces 12a and 12b and the side face 16 by being chamfered obliquely. The chamfered faces 18a and 18b each may be called a “C face”.

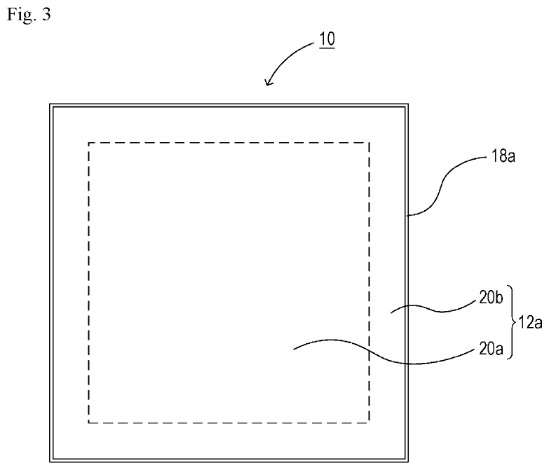

FIG. 3 is a plan view of the first main surface 12a.

As illustrated in FIG. 3, the first main surface 12a includes a first area 20a located around the center of the substrate 10 and a second area 20b located outside the first area 20a.

The first area 20a is a substantially quadrangular area having a size of 132 mm×132 mm or larger. The size “132 mm×132 mm” is the size of an area in which a transfer pattern is formed on a thin film when a transfer mask (for example, a reflective mask) is manufactured with the mask blank substrate 10. The size “132 mm×132 mm” is the size of a square area having a 132 mm side with reference to the center of the substrate 10. Note that any size of an area mentioned below also indicates a size with reference to the center of the substrate 10.

The flatness of the first area 20a is preferably 100 nm or less, more preferably 50 nm or less, and still more preferably 30 nm or less. The flatness refers to a numerical value (absolute value) representing a difference in height between the highest point and the lowest point on a plane with reference to the least squares plane.

The second area 20b is a frame-like area located outside the first area 20a. The second area 20b is preferably an area outside a substantially quadrangular 148 mm×148 mm area located around the center. The size “148 mm×148 mm” is an area size that allows a surface shape measuring apparatus to precisely measure the flatness of the substrate 10. Note that the second area 20b does not include the chamfered face 18a.

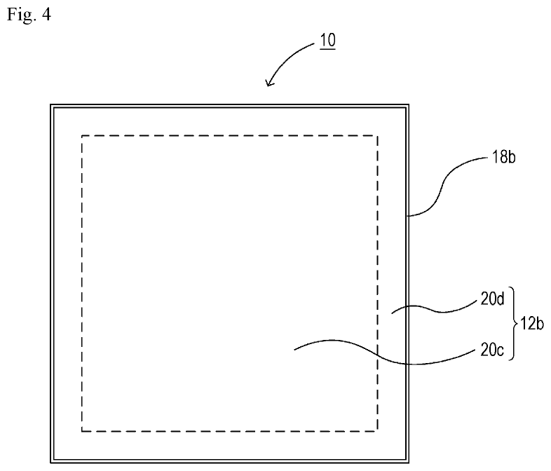

FIG. 4 is a plan view of the second main surface 12b (back surface).

As illustrated in FIG. 4, the second main surface 12b includes a third area 20c located around the center of the substrate 10 and a fourth area 20d located outside the third area 20c.

The third area 20c is a substantially quadrangular area preferably having a size of 142 mm×142 mm or larger. The size “142 mm×142 mm” is the size of an area in which the back surface is required to be flat on a transfer mask that is manufactured with the mask blank substrate 10 (for example, a reflective mask), that is, an area in which the back surface is required to have a flatness of a predetermined value or less. The flatness of the third area 20c is preferably 100 nm or less, more preferably 50 nm or less, and still more preferably 30 nm or less.

The third area 20c preferably has a size of 146 mm×146 mm or smaller. The size “146 mm×146 mm” can be an area in which the second main surface 12b is attracted to a mask stage of an exposure apparatus by an electrostatic chuck. Since an area that is not attracted by an electrostatic chuck need not have a very high flatness, the third area 20c preferably has a size of 146 mm×146 mm or smaller.

The fourth area 20d is a frame-like area located outside the third area 20c. The fourth area 20d is preferably an area outside a substantially quadrangular 148 mm×148 mm area located around the center. The size “148 mm×148 mm” is an area size that allows a surface shape measuring apparatus to precisely measure the flatness of the substrate 10. Note that the fourth area 20d does not include the chamfered face 18b.

The mask blank substrate 10 of the present embodiment is characterized in that the angle α formed between the least squares plane of the first area 20a and the least squares plane of the third area 20c is less than 1.2°. The following describes in detail how the angle α is determined.

First, the surface shape of the entire first main surface 12a (152 mm×152 mm) is measured by using a surface shape measuring apparatus. As the surface shape measuring apparatus, a white light interferometer, a laser interferometer, a laser displacement meter, an ultrasonic displacement meter, a contact type displacement meter, or the like can be used, and it is preferable to use a white light interferometer (for example, NewView 6300 manufactured by Zygo Corporation) or a laser interferometer (for example, “UltraFlat 200” manufactured by Tropel Corporation).

When the surface shape of the substrate 10 is measured by using a surface shape measuring apparatus, the measurement can be done in a state where the substrate 10 is substantially upright (for example, the substrate 10 is inclined by 2° with respect to the vertical direction) in order to reduce distortion of the substrate 10 due to gravity.

During the measurement, the first main surface 12a is divided into a plurality of areas in a grid (for example, 33 μm×33 μm areas) by the surface shape measuring apparatus. Then, for each of the divided areas, the distance (height) from a certain reference plane set by the surface shape measuring apparatus to the first main surface 12a is measured. A set of height data pieces measured for the individual areas is the shape data of the first main surface 12a.

After the shape data of the first main surface 12a is measured, the least squares plane of the first area 20a is determined by using the shape data obtained by the measurement. For example, assuming that the reference plane for measurement is an xy plane and the height direction from the reference plane is a z direction, the least squares plane of the first area 20a is determined to be a function of xyz (a₁x+b₁y+c₁z+d₁=0).

Next, shape data of the second main surface 12b (back surface) is determined by using the shape data of the first main surface 12a and the thickness data of the substrate 10. That is, by using the shape data (height data) measured in a certain area of the first main surface 12a and the thickness data of the substrate 10 measured in the same area, the shape data (height data) of the second main surface 12b (back surface) in that area can be determined. A laser interferometer, for example, can be used to measure the thickness data of the substrate 10.

Note that another method may be used to measure the shape data of the second main surface 12b (back surface). For example, a three-dimensional shape measuring apparatus may be used to measure the shape data of the second main surface 12b (back surface).

After the shape data of the second main surface 12b is measured, the least squares plane of the third area 20c is determined by using the shape data obtained by the measurement. For example, assuming that the reference plane for measurement is an xy plane and the height direction from the reference plane is a z direction, the least squares plane of the third area 20c is determined to be a function of xyz (a₂x+b₂y+c₂z+d₂=0).

The angle α formed between the least squares plane of the first area 20a (a₁x+b₁y+c₁z+d₁=0) and the least squares plane of the third area 20c (a₂x+b₂y+c₂z+d₂=0) can be determined by, for example, the formula (1) below.

$$\begin{matrix}[ Formula 1 ] & \\ cosα = \frac{\vert {a}_{1} {a}_{2} + {b}_{1} {b}_{2} + {c}_{1} {c}_{2} \vert}{\sqrt{{a}_{1}^{2} + {b}_{1}^{2} + {c}_{1}^{2}} \sqrt{{a}_{2}^{2} + {b}_{2}^{2} + {c}_{2}^{2}}} & ( 1 )\end{matrix}$$

Regarding the mask blank substrate 10 of the present embodiment, the angle α formed between the least squares plane of the first area 20a and the least squares plane of the third area 20c is set to less than 1.2° for the reason described below.

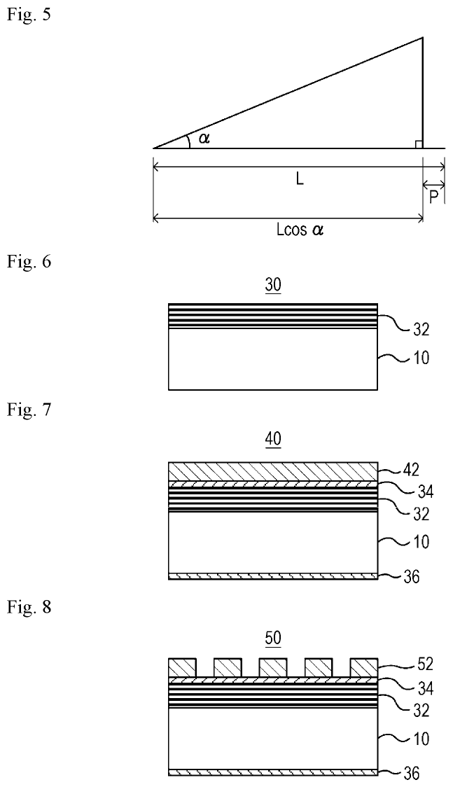

As illustrated in FIG. 5, when a plane having a length L of one side is rotated by an angle α, the length of the projection of the plane that has been rotated onto the plane prior to the rotation is L×cos α. That is, in a case where a certain plane is rotated by an angle α, the maximum value P of a distance (shift amount) by which a point on the plane is shifted is expressed by the formula (2) below.

P=L−L×cos α (2)

As described above, when the shape of the first main surface 12a is measured by a surface shape measuring apparatus, the first main surface 12a is divided into a plurality of areas in a grid. Letting Pg be the size of a single grid, if the condition “P<Pg” can be satisfied, the shift amount does not exceed Pg. Therefore, it is made possible to accurately associate the shape data measured in a certain area of the front surface of the substrate with the shape data of the back surface measured at a position opposed to the area.

Letting Lm be the size of an area in which the flatness of the substrate 10 can be accurately measured by a surface shape measuring apparatus, the maximum value P of a shift amount generated when the plane measured by the surface shape measuring apparatus is rotated by an angle α can be determined by substituting Lm for L in the above formula (2). That is, the maximum value P of a shift amount is expressed by the formula (3) below.

P=Lm−Lm×cos α (3)

Combining the above formula (3) with the above-mentioned condition “P<Pg” provides the formula (4) below.

Lm−Lm×cos α<Pg (4)

Substituting 148 mm (=148,000 μm) for Lm and 33 μm for Pg in the above formula (4) provides a calculation result of α<1.2°. As the grid size is smaller, more detailed shape data can be obtained, and therefore, Pg is preferably 33 μm or less, more preferably 24 μm or less, and still more preferably 15 μm or less. Note that an extremely small grid size requires much time to measure the shape data, and therefore Pg is preferably 9 μm or more. In addition, the maximum value P of a shift amount is preferably Pg/3 or less, and more preferably Pg/5 or less.

From this result, the angle α formed between the least squares plane of the first area 20a and the least squares plane of the third area 20c is less than 1.2°. The angle α is preferably less than 1.0°, and more preferably less than 0.8°. When the angle α formed between the least squares plane of the first area 20a and the least squares plane of the third area 20c is less than 1.2°, the shape data measured in a certain area of the front surface of the substrate and the shape data of the back surface measured at a position opposed to that area can be accurately associated with each other.

In general, an area on the periphery of the first main surface 12a often has irregularities in the surface shape due to, for example, the influence of processing of an end portion of the substrate 10. Therefore, for calculation of the least squares plane, it is preferable to use the shape data covering not the entire first main surface 12a but an area around the center excluding the peripheral area. That is, for calculation of the least squares plane of the first main surface 12a, it is preferable to use the shape data of the first area 20a, which is an area around the center. The first area 20a preferably has a size of 132 mm×132 mm, which is the size of an area on which a transfer pattern is formed.

Likewise, an area on the periphery of the second main surface 12b often has irregularities in the surface shape due to, for example, the influence of processing of an end portion of the substrate 10. Therefore, for calculation of the least squares plane, it is preferable to use the shape data covering not the entire second main surface 12b but an area around the center excluding the peripheral area. That is, for calculation of the least squares plane of the second main surface 12b, it is preferable to use the shape data of the third area 20c, which is an area around the center. The third area 20c preferably has a size of 142 mm×142 mm or larger, which is the size of an area in which the back surface of the substrate 10 is required to be flat (required to have a flatness equal to or less than a predetermined value).

In the mask blank substrate 10 of the present embodiment, the PV value of a surface of each of the second area 20b and the fourth area 20d is 400 nm or less, and preferably 310 nm or less. The PV value of the second area 20b is a numerical value (absolute value) representing the height difference between the highest point and the lowest point on the plane with reference to the least squares plane of the first area 20a. The PV value of the fourth area 20d is a numerical value (absolute value) representing the height difference between the highest point and the lowest point on the plane with reference to the least squares plane of the third area 20c. The PV value of a surface of each of the second area 20b and the fourth area 20d is set to 400 nm or less for the reason described below.

Irregularities (heights from the reference plane) of a surface of the substrate can be measured by a surface shape measuring apparatus. However, in a case where a surface of the periphery of the substrate is inclined beyond a certain degree, it may be difficult to precisely measure irregularities of a surface of the substrate by using a surface shape measuring apparatus. The formula (5) below expresses the maximum value of inclination with which irregularities of a substrate surface can be precisely measured by a surface shape measuring apparatus.

Z=β×X (5)

In the above formula (5), X represents a horizontal distance (mm) on the substrate. Z represents the height (μm) of the substrate surface. Although β is a value dependent on the surface shape measuring apparatus, a small value is employed for β in order to make the present disclosure applicable to any surface shape measuring apparatus. In the case of a laser interferometer, β=0.2178, for example. In the case of a white interferometer, β is a higher value.

In the first main surface 12a (152 mm×152 mm), the second area 20b is an area outside the 148 mm×148 mm area located around the center. The chamfered face 18a on the outermost periphery of the first main surface 12a has a width Wa of 0.4±0.2 mm. Therefore, the width of the second area 20b therebetween is as follows.

Maximum width value of second area 20b={152−148−(2×0.2)}/2=1.8 [mm]

Minimum width value of second area 20b={152−148−(2×0.6)}/2=1.4 [mm]

In the second main surface 12b (152 mm×152 mm), the fourth area 20d is an area outside the 148 mm×148 mm area located around the center. The chamfered face 18b on the outermost periphery of the second main surface 12b has a width Wb of 0.4±0.2 mm. Therefore, the width of the fourth area 20d therebetween is as follows.

Maximum width value of fourth area 20d={152−148−(2×0.2)}/2=1.8 [mm]

Minimum width value of fourth area 20d={152−148−(2×0.6)}/2=1.4 [mm]

Therefore, the width of each of the second area 20b and the fourth area 20d is 1.4 to 1.8 [mm].

Substituting β=0.2178 and X=1.4 to 1.8 into the above formula (5) gives Z=0.305 to 0.392 [μm]. From this result, when the absolute value of a change in height in the second area 20b and the fourth area 20d is smaller than 0.305 to 0.392 [μm], the inclination of the outer periphery of the substrate is sufficiently small, and therefore, irregular shapes of a substrate surface can be accurately measured by a surface shape measuring apparatus.

In other words, when the PV value of the surface of each of the second area 20b and the fourth area 20d is 400 nm or less (preferably 310 nm or less), irregular shapes of a substrate surface can be precisely measured by a surface shape measuring apparatus.

The mask blank substrate 10 of the present embodiment may be a transmissive mask blank substrate or a reflective mask blank substrate.

Any material may be used for a transmissive mask blank substrate for ArF excimer laser exposure as long as the material has light transmissivity with respect to an exposure wavelength. In general, synthetic quartz glass is used. Other materials that may be used include aluminosilicate glass, soda-lime glass, borosilicate glass, and alkali-free glass.

A material of the reflective mask blank substrate for EUV exposure preferably has low thermal expansion properties. For example, so-called multi-component glass such as SiO₂—TiO₂-based glass (binary (SiO₂—TiO₂) and ternary (SiO₂—TiO₂—SnO₂ and the like)), for example, SiO₂—Al₂O₃—Li₂O-based crystallized glass, can be used. Instead of the above-mentioned glass, a substrate made of silicon, metal, or the like can also be used. Examples of the metal substrate include an invar alloy (Fe—Ni-based alloy).

As described above, since a mask blank substrate for EUV exposure is required to have low thermal expansion properties, a multi-component glass material is used for the substrate. However, such a material poses a problem that high smoothness is less likely to be obtained as compared with synthetic quartz glass. In order to solve the problem, a thin film (base layer) made of a metal, an alloy, or a material containing at least one of oxygen, nitrogen, and carbon in addition thereto may be formed on the substrate made of a multi-component glass material.

As a material of the thin film, for example, Ta (tantalum), an alloy containing Ta, or a Ta compound containing at least one of oxygen, nitrogen, and carbon in addition thereto is preferably used. As the Ta compound, for example, TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, and TaSiCON can be used. Among these Ta compounds, TaN, TaON, TaCON, TaBN, TaBON, TaBCON, TaHfN, TaHfON, TaHfCON, TaSiN, TaSiON, and TaSiCON, which contain nitrogen (N), are more preferably used.

Regarding the mask blank substrate 10 of the present embodiment, a processing method used for satisfying the condition that the angle α formed between the least squares plane of the first area 20a and the least squares plane of the third area 20c is less than 1.2° is not particularly limited. In addition, a processing method used for satisfying the condition that the PV value of the surface of each of the second area 20b and the fourth area 20d is 400 nm or less is not particularly limited.

A method of manufacturing the mask blank substrate 10 of the present embodiment includes: measuring the surface shape of the first main surface 12a to obtain the shape data of the first main surface 12a; calculating the shape data of the second main surface 12b using the thickness data of the substrate 10; determining the least squares planes of the first area 20a and the third area 20c from the shape data of the first main surface 12a and the shape data of the second main surface 12b, respectively; and selecting the substrate 10 in which the angle α formed between the least squares plane of the first area 20a and the least squares plane of the third area 20c is less than 1.2° and the PV value of the surface of each of the second area 20b and the fourth area 20d is 400 nm or less.

In addition, a conductive film 36 may be formed on the second main surface 12b of the selected substrate 10 to manufacture a substrate with a conductive film. A multilayer reflective film 32 in which high refractive index layers and low refractive index layers are alternately layered may be formed on the first main surface 12a of the selected substrate 10 to manufacture a substrate with a multilayer reflective film. An absorber film 42 serving as a transfer pattern may be formed on the multilayer reflective film 32 or on the protective film 34 on the first main surface 12a of the selected substrate 10 to manufacture a reflective mask blank.

[Substrate with Conductive Film]

In the mask blank substrate 10 of the present embodiment, a conductive film may be formed on the second main surface 12b so that the transfer mask is attracted to a mask stage of an exposure apparatus by an electrostatic chuck. Note that, in the second main surface 12b, a 146 mm×146 mm area around the center is the area in which the transfer mask is attracted to a mask stage by an electrostatic chuck.

The shape data of the front surface and the back surface of the substrate 10 may be measured in a state where the conductive film is formed on the second main surface 12b of the substrate 10. That is, the shape data of the first main surface and the second main surface (back surface) of the substrate with a conductive film may be measured by a surface shape measuring apparatus. From the shape data obtained by the measurement, the angle α formed between the least squares plane of the first area and the least squares plane of the third area may be determined.

In the substrate with a conductive film of the present embodiment, the angle α formed between the least squares plane of the first area and the least squares plane of the third area may be less than 1.2°. The angle α is preferably less than 1.0°, and more preferably less than 0.8°.

That is, the present disclosure may have the following aspect.

A substrate with a conductive film, the substrate having a substantially quadrangular planar shape, having a size of 152 mm×152 mm, and including a first main surface on which a transfer pattern is formed and a second main surface that is opposed to the first main surface and is to be electrostatically chucked to a mask stage of an exposure apparatus, the second main surface having a conductive film for the electrostatic chuck formed on the second main surface, in which

the first main surface includes a first area located around a center and a second area located outside the first area,

the second main surface includes a third area located around a center and a fourth area located outside the third area, and

an angle α formed between a least squares plane of the first area and a least squares plane of the third area is less than 1.2°.

A method of manufacturing the substrate with a conductive film of the present embodiment includes: forming a conductive film on a second main surface of a mask blank substrate; measuring surface shape of a first main surface to obtain shape data of the first main surface; calculating the shape data of the second main surface on which the conductive film is formed using thickness data of the substrate; determining least squares planes of a first area and a third area from the shape data of the first main surface and the shape data of the second main surface, respectively; and selecting the substrate with the conductive film in which an angle α formed between the least squares plane of the first area and the least squares plane of the third area is less than 1.2°.

A multilayer reflective film in which high refractive index layers and low refractive index layers are alternately layered may be formed on the first main surface of the selected substrate with a conductive film to manufacture a substrate with a multilayer reflective film. An absorber film serving as a transfer pattern may be formed on the multilayer reflective film or on the protective film on the first main surface of the selected substrate with a conductive film to manufacture a reflective mask blank.

[Substrate with Multilayer Reflective Film]

Next, a substrate with a multilayer reflective film of the present embodiment will be described.

FIG. 6 is a schematic diagram illustrating a substrate with a multilayer reflective film 30 of the present embodiment.

The substrate with a multilayer reflective film 30 of the present embodiment has a configuration in which a multilayer reflective film 32 is formed on the first main surface 12a, which is the side on which a transfer pattern of the mask blank substrate 10 is formed. The multilayer reflective film 32 imparts a function of reflecting EUV light in a reflective mask for EUV lithography, and includes a multilayer film in which elements having different refractive indexes are periodically layered.

The material of the multilayer reflective film 32 is not particularly limited as long as the material reflects EUV light, and the reflectance of the multilayer reflective film 32 alone is usually 65% or more and the upper limit thereof is usually 73%. In general, such a multilayer reflective film 32 includes a multilayer reflective film in which thin films (high refractive index layers) made of a material having a high refractive index and thin films (low refractive index layers) made of a material having a low refractive index are alternately layered for about 40 to 60 periods.

For example, as the multilayer reflective film 32 for EUV light having a wavelength of 13 to 14 nm, a Mo/Si periodic layered film in which Mo films and Si films are alternately layered for about 40 periods is preferably used. Other examples of the multilayer reflective film used in an EUV light region includes a Ru/Si periodic multilayer film, a Mo/Be periodic multilayer film, a Mo compound/Si compound periodic multilayer film, a Si/Nb periodic multilayer film, a Si/Mo/Ru periodic multilayer film, a Si/Mo/Ru/Mo periodic multilayer film, and a Si/Ru/Mo/Ru periodic multilayer film.

The multilayer reflective film 32 can be formed by a method known in the art. For example, each layer can be formed by a magnetron sputtering method, an ion beam sputtering method, or the like. In the case of the above-mentioned Mo/Si periodic multilayer film, for example, a Si film having a thickness of several nanometers is first formed on the substrate 10 using a Si target by, for example, an ion beam sputtering method. Then, a Mo film having a thickness of several nanometers is formed using a Mo target. This formation is counted as one period and the Si film and the Mo film can be layered for 40 to 60 periods to form the multilayer reflective film 32.

A protective film 34 (see FIG. 7) may be formed on the multilayer reflective film 32 formed as described above, in order to protect the multilayer reflective film 32 from dry etching and wet cleaning in a process of manufacturing the reflective mask for EUV lithography.

Examples of the material of the protective film 34 include a material containing at least one selected from the group consisting of Ru, Ru—(Nb, Zr, Y, B, Ti, La, Mo), Si—(Ru, Rh, Cr, B), Si, Zr, Nb, La, and B. When a material containing ruthenium (Ru), among others, is used, the reflectance characteristics of the multilayer reflective film are improved. Specifically, Ru and Ru—(Nb, Zr, Y, B, Ti, La, Mo) are preferred materials of the protective film 34. Such a protective film is particularly effective in a case where the absorber film includes a Ta-based material and the absorber film is patterned by dry etching with a Cl-based gas.

As described above, for the purpose of electrostatic chucking, the conductive film 36 (see FIG. 7) may be formed on the substrate 10 on the surface opposite to the surface in contact with the multilayer reflective film 32. An electrical characteristic (sheet resistance) required of the conductive film 36 is usually 100Ω/□ less. The conductive film 36 can be formed by a known method. For example, the conductive film 36 can be formed by a magnetron sputtering method or an ion beam sputtering method using a metal target such as Cr or Ta or an alloy thereof.

The above-described base layer may be formed between the substrate 10 and the multilayer reflective film 32. The base layer may be formed for the purposes of improving smoothness of the main surface of the substrate 10, reducing defects, improving reflectance of the multilayer reflective film 32, reducing stress in the multilayer reflective film 32, and the like.

The shape data of the front surface and the back surface of the substrate 10 may be measured in a state where the multilayer reflective film 32 is formed on the first main surface 12a of the substrate 10 or the multilayer reflective film 32 and the protective film 34 are formed thereon. That is, the shape data of the first main surface and the second main surface (back surface) of the substrate with a multilayer reflective film may be measured by a surface shape measuring apparatus. The shape data of the front surface and the back surface of the substrate 10 may also be measured in a state where the conductive film 36 is formed on the second main surface 12b. From the shape data obtained by the measurement, the angle α formed between the least squares plane of the first area and the least squares plane of the third area may be determined.

In the substrate with a multilayer reflective film of the present embodiment, the angle α formed between the least squares plane of the first area and the least squares plane of the third area may be less than 1.2°. The angle α is preferably less than 1.0°, and more preferably less than 0.8°.

That is, the present disclosure may have the following aspect.

A substrate with a multilayer reflective film, the substrate having a substantially quadrangular planar shape, having a size of 152 mm×152 mm, and including a first main surface on which a transfer pattern is formed and a second main surface that is opposed to the first main surface and is to be electrostatically chucked to a mask stage of an exposure apparatus, the first main surface having a multilayer reflective film that reflects EUV light and a protective film that protects the multilayer reflective film formed in the order mentioned on the first main surface, and the second main surface having a conductive film for the electrostatic chuck formed on the second main surface, in which

the first main surface includes a first area located around a center and a second area located outside the first area,

the second main surface includes a third area located around a center and a fourth area located outside the third area, and

an angle α formed between a least squares plane of the first area and a least squares plane of the third area is less than 1.2°.

A method of manufacturing the substrate with a multilayer reflective film of the present embodiment includes: forming a multilayer reflective film on a first main surface of a mask blank substrate; measuring surface shape of the first main surface on which the multilayer reflective film is formed to obtain shape data of the first main surface; calculating the shape data of a second main surface using thickness data of the substrate; determining least squares planes of a first area and a third area from the shape data of the first main surface and the shape data of the second main surface, respectively; and selecting the substrate with the multilayer reflective film in which an angle α formed between the least squares plane of the first area and the least squares plane of the third area is less than 1.2°.

In addition, a conductive film may be formed on the second main surface of the selected substrate with the multilayer reflective film to manufacture a substrate with a conductive film. An absorber film serving as a transfer pattern may be formed on the multilayer reflective film or on the protective film of the selected substrate with the multilayer reflective film to manufacture a reflective mask blank.

[Reflective Mask Blank]

Next, a reflective mask blank of the present embodiment will be described.

FIG. 7 is a schematic diagram illustrating a reflective mask blank 40 of the present embodiment.

The reflective mask blank 40 of the present embodiment has a configuration in which an absorber film 42 serving as a transfer pattern is formed on the protective film 34 of the above-described substrate with a multilayer reflective film 30.

The material of the absorber film 42 is not particularly limited as long as the material has a function of absorbing EUV light. For example, Ta (tantalum) alone or a material containing Ta as a main component is preferably used. The material containing Ta as a main component is, for example, an alloy of Ta. Alternatively, examples of the material containing Ta as a main component include a material containing Ta and B, a material containing Ta and N, a material containing Ta and B and further containing at least one of O and N, a material containing Ta and Si, a material containing Ta, Si, and N, a material containing Ta and Ge, and a material containing Ta, Ge, and N.

The reflective mask blank of the present embodiment is not limited to the configuration illustrated in FIG. 7. For example, a resist film serving as a mask for patterning the absorber film 42 may be formed on the absorber film 42. The resist film formed on the absorber film 42 may be of positive type or negative type. In addition, the resist film formed on the absorber film 42 may be intended for electron beam drawing or for laser drawing. Furthermore, a hard mask (etching mask) film may be formed between the absorber film 42 and the resist film.

The shape data of the front surface and the back surface may be measured in a state in which the absorber film 42 is formed on the multilayer reflective film 32 or in a state in which the absorber film 42 and the hard mask film are formed on the multilayer reflective film 32. That is, the shape data of the first main surface and the second main surface (back surface) of the reflective mask blank may be measured by a surface shape measuring apparatus. The shape data of the front surface and the back surface of the substrate 10 may also be measured in a state where the conductive film 36 is formed on the second main surface 12b. From the shape data obtained by the measurement, the angle α formed between the least squares plane of the first area and the least squares plane of the third area may be determined.

In the reflective mask blank of the present embodiment, the angle α formed between the least squares plane of the first area and the least squares plane of the third area may be less than 1.2°. The angle α is preferably less than 1.0°, and more preferably less than 0.8°.

That is, the present disclosure may have the following aspect.

A reflective mask blank having a substantially quadrangular planar shape, having a size of 152 mm×152 mm, and including a first main surface on which a transfer pattern is formed and a second main surface that is opposed to the first main surface and is to be electrostatically chucked to a mask stage of an exposure apparatus, the first main surface having a multilayer reflective film that reflects EUV light, a protective film that protects the multilayer reflective film, and an absorber film that absorbs the EUV light formed in the order mentioned on the first main surface, and the second main surface having a conductive film for the electrostatic chuck formed on the second main surface, in which

the first main surface includes a first area located around a center and a second area located outside the first area,

the second main surface includes a third area located around a center and a fourth area located outside the third area, and

an angle α formed between a least squares plane of the first area and a least squares plane of the third area is less than 1.2°.

A method of manufacturing a reflective mask blank of the present embodiment includes: forming a multilayer reflective film, a protective film, and an absorber film on a first main surface of a mask blank substrate; measuring surface shape of a first main surface on which the absorber film is formed to obtain shape data of the first main surface; calculating the shape data of a second main surface using thickness data of the substrate; determining least squares planes of a first area and a third area from the shape data of the first main surface and the shape data of the second main surface, respectively; and selecting the reflective mask blank in which an angle α formed between the least squares plane of the first area and the least squares plane of the third area is less than 1.2°.

In addition, the conductive film 36 may be formed on the second main surface of the selected reflective mask blank.

[Reflective Mask]

Next, a reflective mask 50 of the present embodiment will be described.

FIG. 8 is a schematic diagram illustrating the reflective mask 50 of the present embodiment.

The reflective mask 50 of the present embodiment includes an absorber film pattern 52 obtained by patterning the absorber film 42 of the reflective mask blank 40 described above. In the reflective mask 50 of the present embodiment, exposure light is absorbed in a certain portion of the absorber film pattern 52, while the exposure light is reflected in a portion where the multilayer reflective film 32 (or the protective film 34) is exposed by removing the absorber film 42. Thus, the reflective mask 50 of the present embodiment can be used as, for example, a reflective mask for the lithography that uses EUV light as exposure light.

[Method of Manufacturing Semiconductor Device]

A semiconductor device can be manufactured by a lithography process that employs the reflective mask 50 described above and an exposure apparatus. Specifically, the absorber film pattern 52 of the reflective mask 50 is transferred to a resist film formed on a semiconductor substrate. After that, through steps including a development and a cleaning, a semiconductor device in which a pattern (a circuit pattern, for example) is formed on a semiconductor substrate can be manufactured.

### Examples

As the mask blank substrate 10, a SiO₂—TiO₂-based glass substrate having a size of 152 mm×152 mm and a thickness of 6.4 mm was prepared. The front surface and the back surface of the glass substrate were polished stepwise with cerium oxide abrasive grains or colloidal silica abrasive grains by using a double-side polishing apparatus. After that, the front surface of the glass substrate was treated with low-concentration fluosilicic acid. The surface roughness of the resulting glass substrate was measured with an atomic force microscope. As a result, the root mean square roughness (Rq) of the front surface of the glass substrate was found to be 0.15 nm.

The shape of the front surface of the glass substrate (surface morphology, flatness) was measured using a surface shape measuring apparatus (UltraFlat 200 manufactured by Tropel Corporation). The surface shape was measured at 1024×1024 points in a 148 mm×148 mm area excluding the peripheral area of the glass substrate. As a result, the flatness of the front surface of the glass substrate was found to be 290 nm (convex shape). The measurement result of the shape (flatness) of the surface of the glass substrate was stored in a computer for each measurement point as height information with respect to a certain reference plane. In addition, the shape data of the back surface of the glass substrate was determined by using thickness data of the glass substrate. Specifically, by using the shape data (height data) measured in a certain area of the glass substrate and the thickness data of the glass substrate measured in the same area, the shape data (height data) of the glass substrate (back surface) in that area was determined. A laser interferometer was used to measure the thickness data of the glass substrate. The angle α formed between the reference plane of the front surface of the glass substrate and the reference plane of the back surface thereof was determined by calculation. Taking into consideration the angle α, a comparison was made for each measurement point between the height information and the reference value 20 nm (convex shape) of the front surface flatness required for the glass substrate, and the difference therebetween (the required amount of removal) was calculated by a computer. Likewise, a comparison was made including the angle α between the height information and the reference value 20 nm of the back surface flatness, and the difference (the required amount of removal) was calculated by a computer.

Next, conditions for local surface processing were set in accordance with the required amount of removal for each processing spot area on the front surface of the glass substrate. A dummy substrate was used in advance to spot-process the dummy substrate for a certain period of time without moving the substrate in the same manner as in the actual processing. The shape of the dummy substrate was measured by the apparatus that was used for measuring the shapes of the front surface and the back surface. The processing volume of a spot per unit time was calculated. Then, in accordance with the spot information and the required amount of removal obtained from information regarding the surface shape of the glass substrate, the scanning speed for raster-scanning the glass substrate was determined.

In accordance with the processing conditions that have been set, the surface shape was adjusted by local surface processing so that the flatness of the front surface and the back surface of the glass substrate was equal to or less than the above-described reference value by a magneto-rheological finishing (MRF) processing method using a substrate finishing apparatus based on a magnetic fluid (manufactured by QED Technologies Inc.). The magneto-rheological fluid used for the processing contained an iron component. The polishing slurry was an aqueous alkali solution+an abrasive (about 2 wt %), and cerium oxide was used as the abrasive. The maximum processing allowance was 150 nm and the processing time was 30 minutes.

After that, the glass substrate was immersed in a cleaning tank containing a hydrochloric acid aqueous solution (temperature: about 25° C.) in about 10% concentration for about 10 minutes, and then rinsed with pure water, and dried with isopropyl alcohol (IPA).

Next, the front surface and the back surface of the glass substrate were finish-polished under the following conditions.

Processing solution: alkali aqueous solution (NaOH)+abrasive (concentration: about 2 wt %)

Abrasive: colloidal silica, average particle size: about 70 nm

Polishing table rotation speed: about 1 to 50 rpm

Processing pressure: about 0.1 to 10 kPa

Polishing time: about 1 to 10 minutes

After that, the glass substrate was washed with an alkaline aqueous solution (NaOH) to obtain a mask blank substrate 10 for EUV exposure.

The shape (height) of the first main surface 12a of the obtained mask blank substrate 10 was measured by using a surface shape measuring apparatus (NewView 6300 manufactured by Zygo Corporation). Specifically, a 148 mm×148 mm area of the first main surface 12a was divided into 12 μm×12 μm areas in a grid, and the surface shape was measured for each of the divided areas. The least squares plane of the first area 20a was determined by using the shape data obtained by the measurement. The flatness of the first area 20a was 20 nm.

In addition, the shape data of the second main surface 12b (back surface) was determined by using the shape data of the first main surface 12a and the thickness data of the substrate 10. That is, by using the shape data (height data) measured in a certain area of the first main surface 12a and the thickness data of the substrate 10 measured in the same area, the shape data (height data) of the second main surface 12b (back surface) in that area was determined. A laser interferometer was used to measure the thickness data of the substrate 10. The least squares plane of the third area 20c was determined by using the shape data obtained by the measurement. The flatness of the third area 20c was 22 nm.

The angle α formed between the least squares plane of the first area 20a and the least squares plane of the third area 20c was determined by calculation. The result was α=0.73°.

Next, the PV value of the surface of each of the second area 20b and the fourth area 20d of the obtained mask blank substrate 10 was measured by using a surface shape measuring apparatus (NewView 6300 manufactured by Zygo Corporation). Each of the second area 20b and the fourth area 20d was set to an area outside a 148 mm×148 mm area located around the center. As a result, the PV value of the second area 20b was found to be 302 nm. The PV value of the fourth area 20d was 296 nm.

By using the shape data of the first main surface 12a and the shape data of the second main surface 12b of the mask blank substrate 10, the shape of the first main surface 12a as of the time after the mask blank substrate 10 is attracted to a mask stage of an exposure apparatus by an electrostatic chuck was determined through simulation. Specifically, the shape (height) of the first main surface 12a as of the time after the substrate is attracted to the mask stage of the exposure apparatus was determined by adding the shape data of the first main surface 12a to the shape data of the second main surface 12b for each measurement area. Furthermore, by using the shape data of the first main surface 12a determined through simulation, data about a pattern to be drawn on a resist film formed on a below-described absorber film was corrected.

A conductive back film made of CrN was formed on the second main surface 12b (back surface) of the mask blank substrate 10 by a magnetron sputtering method under the following conditions.

(Conditions): Cr target, Ar+N₂ gas atmosphere (Ar: N₂=90%: 10%), film composition (Cr: 90 atomic %, N: 10 atomic %), film thickness 20 nm

A multilayer reflective film was formed by periodically layering a Mo film/a Si film on the first main surface 12a of the mask blank substrate 10 to produce the substrate with a multilayer reflective film.

Specifically, Mo films and Si films were alternately layered on the substrate by ion beam sputtering (using Ar) with a Mo target and a Si target. The film thickness of the Mo film was 2.8 nm. The film thickness of the Si film was 4.2 nm. The film thickness of the Mo/Si film for one period was 7.0 nm. Such Mo—Si films were layered for 40 periods, and finally, a 4.0 nm-thick Si film was deposited to form the multilayer reflective film.

A protective film containing a Ru compound was formed on the multilayer reflective film. Specifically, a protective film made of a RuNb film was formed on the multilayer reflective film by DC magnetron sputtering in an Ar gas atmosphere using a RuNb target (Ru: 80 atomic %, Nb: 20 atomic %). The film thickness of the protective film was 2.5 nm.

An absorber film was formed on the protective film to produce a reflective mask blank. Specifically, an absorber film including layered films of TaBN (film thickness: 56 nm) and TaBO (film thickness: 14 nm) was formed by DC magnetron sputtering. The TaBN film was formed by reactive sputtering using a TaB target in a mixed gas atmosphere of an Ar gas and a N₂ gas. The TaBO film was formed by reactive sputtering using a TaB target in a mixed gas atmosphere of an Ar gas and an O₂ gas.

A resist film was formed on the absorber film of the reflective mask blank. A pattern was drawn on the resist film by using an electron beam drawing apparatus. For drawing the pattern, the above-described corrected pattern data was used. After the pattern was drawn, a predetermined development process was performed to form a resist pattern on the absorber film.

With the resist pattern serving as a mask, a pattern (absorber pattern) was formed on the absorber film. Specifically, the upper TaBO film was dry-etched with a fluorine-based gas (CF₄ gas), and then the lower TaBN film was dry-etched with a chlorine-based gas (Cl₂ gas).

The resist pattern remaining on the absorber film pattern was removed with hot sulfuric acid, thereby producing an EUV reflective mask. A lithography process employing an exposure apparatus was performed by using the produced reflective mask, thereby producing a semiconductor device. Specifically, the absorber pattern of the reflective mask was transferred to the resist film formed on a semiconductor substrate. After that, through steps including a development and a cleaning, a semiconductor device in which a circuit pattern was formed on the semiconductor substrate was produced. On the semiconductor substrate of the produced semiconductor device, the circuit pattern was accurately formed as designed.

### Comparative Example

In a comparative example, a mask blank substrate was produced in the same manner as in the above example. However, the local surface processing in the above example was not performed.

In the mask blank substrate produced in the comparative example, the angle α formed between the least squares plane of the first area 20a and the least squares plane of the third area 20c was 1.3°.

In the mask blank substrate produced in the comparative example, the PV value of a surface of each of the second area 20b and the fourth area 20d was 421 nm.

As in the example above, by using the mask blank substrate produced in the comparative example, a substrate with a conductive film, a substrate with a multilayer reflective film, a reflective mask blank, and a reflective mask were produced. A lithography process employing an exposure apparatus was performed by using the produced reflective mask, thereby producing a semiconductor device. Specifically, the absorber pattern of the reflective mask was transferred to the resist film formed on a semiconductor substrate. After that, through steps including a development and a cleaning, a semiconductor device in which a circuit pattern was formed on the semiconductor substrate was produced. As a result of inspecting the circuit pattern on the produced semiconductor substrate, it was confirmed that the circuit pattern in some portions was not accurately formed as designed.

### REFERENCE SIGNS LIST

10 Mask blank substrate
12a First main surface
12b Second main surface
20a First area
20b Second area
20c Third area
20d Fourth area
30 Substrate with multilayer reflective film
40 Reflective mask blank
50 Reflective mask

1. A mask blank substrate having a substantially quadrangular planar shape and a size of 152 mm×152 mm, the mask blank substrate comprising:
a first main surface that includes:
a first area around a center of the first main surface, and
a second area located outside the first area, wherein a peak-to-valley (PV) value of the second area is 400 nm or less; and
a second main surface that is opposed to the first main surface and includes:
a third area around a center of the second main surface, and
a fourth area located outside the third area, wherein a PV value of the fourth area is 400 nm or less,
wherein an angle α between a least squares plane of the first area and a least squares plane of the third area is less than 1.2 (one-point-two) degrees.

2. The mask blank substrate according to claim 1, wherein the first area is an area on which a transfer pattern is to be formed and has a size of 132 mm×132 mm or more.

3. The mask blank substrate according to claim 1, wherein the third area has a size of 142 mm×142 mm or more.

4. The mask blank substrate according to claim 1, wherein the second area is outside a 148 mm×148 mm area around the center of the first main surface, and
wherein the fourth area is outside a 148 mm×148 mm area around the center of the second main surface.

5. The mask blank substrate according to claim 1, wherein the mask blank substrate is a reflective mask blank substrate.

6. A substrate with a conductive film, comprising:
the mask blank substrate according to claim 1; and
a conductive film on the second main surface of the mask blank substrate.

7. A substrate with a multilayer reflective film, the substrate comprising:
the mask blank substrate according to claim 1; and
a multilayer reflective film in which a high refractive index layer and a low refractive index layer are alternately layered, wherein the multilayer reflective film is on the first main surface of the mask blank substrate.

8. A reflective mask blank comprising:
a mask blank substrate,
a multilayer reflective film in which a high refractive index layer and a low refractive index layer are alternately layered, and
an absorber film to serve as a transfer pattern on the multilayer reflective film,
wherein the mask blank substrate has a substantially quadrangular planar shape and a size of 152 mm×152 mm and comprises:
a first main surface that includes:
a first area around a center of the first main surface, and
a second area located outside the first area, wherein a peak-to-valley (PV) value of the second area is 400 nm or less; and
a second main surface that is opposed to the first main surface and includes:
a third area around a center of the second main surface, and
a fourth area located outside the third area, wherein a PV value of the fourth area is 400 nm or less,
wherein an angle α between a least squares plane of the first area and a least squares plane of the third area is less than 1.2 (one-point-two) degrees.

9. A reflective mask comprising:
a mask blank substrate,
a multilayer reflective film in which a high refractive index layer and a low refractive index layer are alternately layered, and
an absorber pattern on the multilayer reflective film, wherein
the mask blank substrate has a substantially quadrangular planar shape and a size of 152 mm×152 mm and comprises:
a first main surface that includes:
a first area around a center of the first main surface, and
a second area located outside the first area, wherein a peak-to-valley (PV) value of the second area is 400 nm or less; and
a second main surface that is opposed to the first main surface and includes:
a third area around a center of the second main surface, and
a fourth area located outside the third area, wherein a PV value of the fourth area is 400 nm or less,
wherein an angle α between a least squares plane of the first area and a least squares plane of the third area is less than 1.2 (one-point-two) degrees.

10. A method of manufacturing a semiconductor device, the method comprising performing a lithography process that employs an exposure apparatus using the reflective mask according to claim 9 to form a transfer pattern on a transfer-receiving object.

11. The reflective mask blank according to claim 8, wherein the first area is an area on which the transfer pattern is to be formed and has a size of 132 mm×132 mm or more.

12. The reflective mask blank according to claim 8, wherein the third area has a size of 142 mm×142 mm or more.

13. The reflective mask blank according to claim 8, wherein the second area is outside a 148 mm×148 mm area around the center of the first main surface, and
wherein the fourth area is outside a 148 mm×148 mm area around the center of the second main surface.

14. The reflective mask according to claim 9, wherein the first area is an area on which the transfer pattern is formed and has a size of 132 mm×132 mm or more.

15. The reflective mask according to claim 9, wherein the third area has a size of 142 mm×142 mm or more.

16. The reflective mask according to claim 9, wherein the second area is outside a 148 mm×148 mm area around the center of the first main surface, and
wherein the fourth area is outside a 148 mm×148 mm area around the center of the second main surface.

17. The mask blank substrate according to claim 1, wherein the second main surface is configured to be electrostatically chucked to a mask stage of an exposure apparatus.
